(19) United States
(12) Patent Application Publication
(10) Pub. No.: US 2005/0268261 A1
(43) Pub. Date: Dec. 1, 2005

(54) Circuit analyzing method and circuit analyzing device

(75) Inventors: Kaori Hatakeyama, Shiga (JP); Yukihiro Sasagawa, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/136,663

(22) Filed: May 25, 2005

(30) Foreign Application Priority Data
May 25, 2004 (JP) P2004-154499

(51) Int. Cl. G01R 27/26; G06F 9/45

(52) U.S. Cl. 716/5; 716/4; 324/358

(57) ABSTRACT

A circuit analyzing device according to the present invention comprises a capacitance value extracting unit for extracting a capacitance value of a functional element from design information including layout information of a semiconductor integrated circuit and a capacitance value outputting unit for displaying the functional element in the semiconductor integrated circuit or a functional-element connecting wiring linked to the functional element on a design drawing including the layout information of the semiconductor integrated circuit in a discriminating manner in accordance with the capacitance value of the functional element, or comprises a per-attribute capacitance value operation unit for executing an operation of the capacitance value per attribute based on a functional-element attribute library in which attribute information of the functional element in the semiconductor integrated circuit is stored and the capacitance value of the functional element and a per-attribute capacitance value outputting unit for outputting the capacitance value per attribute calculated by the per-attribute capacitance value operation unit.

### BACKGROUND OF THE INVENTION

1. Field of the Invention

The present invention relates to a circuit analyzing method and a circuit analyzing device for a semiconductor integrated circuit, more particularly to analysis of power consumption, simplified timing analysis and expediting measures.

2. Description of the Related Art

In recent years, a mobile device is ever-increasingly pursuing a higher facility, while a stationary device is required to reduce power consumption because of an ongoing environmental trend for reducing noises, in response to which, a semiconductor integrated circuit is required to operate with a lower power consumption. In order to achieve a targeted power consumption, a technology for estimating the power consumption in an early stage of designing the circuit is demanded. To respond to the demand, a method of estimating the power consumption of the semiconductor integrated circuit from a capacitance value and a variation rate of each signal line was proposed as a method of estimating the power consumption of the circuit in advance. According to the method of method of estimating the power consumption from the capacitance value and the variation rate of the signal line, the power consumption can be accurately obtained, however, the analysis according to the method is disadvantageously time consuming.

It is necessary to operate the circuit in a manner as close as possible to the practical use in order to calculate the variation rate. However, it is difficult to implement the foregoing power analyzing method in the case in which a net list in an initial stage of the designing process is incomplete. As a result, the analysis is naturally left to a final stage of the designing process, which unfavorably increases an amount of time required for the designing process if any problem occurs in the stage.

According to the foregoing method, it is possible to specify any section consuming a large amount of power from a result of analyzing the power consumption though it is difficult to identify what causes the power consumption to increase.

Under the described circumstances, it is desirable to develop a circuit analyzing device and a circuit analyzing method capable of easily extracting any trouble part in terms of power and speed.

### BRIEF SUMMARY OF THE INVENTION

(1) A circuit analyzing device for a semiconductor integrated device according to the present invention comprises:

a capacitance value extracting unit for extracting a capacitance value of a functional element from design information including layout information of the semiconductor integrated circuit; and
a capacitance value outputting unit for displaying the functional element in the semiconductor integrated circuit or a functional-element connecting wiring linked to the functional element on a design drawing including the layout information of the semiconductor integrated circuit in a discriminating manner in accordance with the capacitance value of the functional element. In this specification, the circuit analyzing device according to the foregoing constitution is referred to as a “circuit analyzing device of a first list”.

According to the foregoing constitution, the capacitance value outputting unit graphically displays the functional element or the functional-element connecting wiring in the discriminating manner based on the capacitance value. Therefore, any part undergoing a trouble, in particular, the functional element or wiring having a large capacitance, can be easily visually grasped, and the trouble part can be thereby efficiently found.

(2) A circuit analyzing device for a semiconductor integrated device according to the present invention comprises:

a capacitance value extracting unit for extracting a capacitance value of a functional element from design information including layout information of the semiconductor integrated circuit; and
a capacitance value/attribute outputting unit for outputting the capacitance value and an attribute of each functional element based on a functional-element attribute library in which attribute information of the functional element in the semiconductor integrated circuit is stored and the capacitance value of the functional element.

In this specification, the circuit analyzing device according to the foregoing constitution is referred to as a “circuit analyzing device of a second list”.

According to the foregoing constitution, the capacitance value/attribute outputting unit outputs the capacitance value and the attribute of the functional element in a combining manner. A dimension of the capacitance value is used as the attribute so that the parthaving a large capacitance value can be extracted, making it easy to analyze the trouble part.

(3) A circuit analyzing device for a semiconductor integrated device according to the present invention comprises:

a capacitance value extracting unit for extracting a capacitance value of a functional element from design information including layout information of the semiconductor integrated circuit;
a per-attribute capacitance value operation unit for executing an operation of the capacitance value per attribute based on a functional-element attribute library in which attribute information of the functional element in the semiconductor integrated circuit is stored and the capacitance value of the functional element; and
a per-attribute capacitance value outputting unit for outputting the capacitance value per attribute calculated by the per-attribute capacitance value operation unit. The term “outputting unit” denotes a broad concept in which display, print, output of electromagnetic data and the like are included. In this specification, the circuit analyzing device according to the foregoing constitution is referred to as a “circuit analyzing device of a third list”.

According to the foregoing constitution, the per-attribute capacitance value operation unit executes the operation of the capacitance value by each attribute and obtains the capacitance value per attribute and thereafter organizes the capacitance values having the same attribute in a group, and the per-attribute capacitance value outputting unit outputs the per-attribute capacitance value. As a result, the capacitance value can be analyzed for each attribute, which makes it easier to analyze the trouble part which is not easily individually detected.

As is obvious from the foregoing description, the components of the device, which are the capacitance value extracting unit, capacitance value outputting unit, capacitance value/attribute outputting unit, per-attribute capacitance value operation unit and per-attribute capacitance value outputting unit may be realized by hardware or software.

Additional objects and advantages of the present invention will be apparent from the following detailed description of preferred embodiments thereof, which are best understood with reference to the accompanying drawings.

### BRIEF DESCRIPTION OF THE DRAWINGS

FIG. 1 is a block diagram illustrating constitutions and facilities of a circuit analyzing device and a circuit analyzing method according to an embodiment 1 of the present invention.

FIG. 2 is an explanatory view of a capacitance model according to the embodiment 1.

FIG. 3 is an explanatory view of a capacitance model according to the embodiment 1.

FIG. 4 is a display example of a capacitance value of a functional element in an entire semiconductor integrated circuit according to the embodiment 1.

FIG. 5 is a display example of the functional element according to the embodiment 1.

FIG. 6 is a block diagram illustrating constitutions and functions of a circuit analyzing device and a circuit analyzing method according to an embodiment 2 of the present invention.

FIG. 7A is an example of a circuit according to the embodiment 2. FIG. 7B is an example of an attribute library regarding the circuit.

FIG. 8A is an example of a circuit-according to an embodiment 3 of the present invention. FIG. 7B is an example of an attribute library regarding the circuit.

### DETAILED DESCRIPTION OF THE PREFERRED EMBODIMENTS

In general, an amount of consumed power and a delay value of a circuit both depend on a capacitance value parasitic on the circuit. Therefore, when the capacitance value is reduced, the circuit can simultaneously achieve a higher speed and lower power consumption.

More specifically, any part undergoing a trouble in terms of power and speed can be more easily and more quickly identified through the analysis of the circuit focusing on the capacitance value.

Further, an approach can be made in an initial stage of a designing process because only the capacitance value is used for the analysis, and a time length required for the entire designing process can be shortened by detecting and dealing with the trouble part having a large capacitance value already in an early stage of the designing process.

Further, the part having the large capacitance value can be visually grasped by graphically displaying a result of analyzing the capacitance value. Accordingly, a factor of the generated problem, examples of which are a layout issue of a large distance between functional elements to be connected and a logic issue of an excessively large number of functional elements to be connected, can be easily identified.

The before-mentioned constitutions can be more specifically broken down into the following modes.

(4) In the circuit analyzing device of the second list recited in (2), the capacitance value/attribute outputting unit displays the functional element or the functional-element connecting wiring on the designing drawing including the layout of the semiconductor integrated circuit in the discriminating manner in accordance with the capacitance value of the functional element. It is affirmed in the constitution that the capacitance value/attribute outputting unit has at least the display facility.

(5) In the circuit analyzing device of the third list recited in (3), the per-attribute capacitance value outputting unit displays the functional element or the functional-element connecting wiring on the designing drawing including the layout of the semiconductor integrated circuit in the discriminating manner in accordance with the per-attribute capacitance value. It is affirmed in the constitution that the per-attribute capacitance value outputting unit has at least the display facility.

According to the foregoing constitutions of (4) and (5), the functional element and the functional-element connecting wiring are graphically displayed in the discriminating manner based on the capacitance value. Accordingly, the trouble part can be easily visually confirmed, which realizes the efficient detection of the trouble part.

(6) In the circuit analyzing device of the third list recited in (3), the per-attribute capacitance value operation unit sums the functional-element capacitance values having the same attribute so that the capacitance value per attribute can be calculated.

According to the foregoing constitution, the attribute whose total of the capacitance values is large can be detected by summing the per-attribute capacitance values, which facilitates the analysis of the trouble part in such a case that it is necessary not only to control the individual functional element but also to collectively control the capacitances of those having the same attribute.

(7) In the circuit analyzing device of the third list recited in (3), the per-attribute capacitance value operation unit divides the total of the capacitance values calculated by summing the functional-element capacitance values having the same attribute by the number of the wirings included in the each attribute and thereby calculates the capacitance value of each wiring per attribute.

According to the foregoing constitution, the attribute with a large capacitance value can be found irrespective of the number of the wirings even in the presence of any difference in the number of the wirings included in each attribute, which facilitates the analysis of the trouble part.

(8) In the circuit analyzing device of the first list recited in (1), the capacitance value outputting unit includes a capacitance conditions setting section for setting conditions for the capacitance to be displayed and a display contents deciding section for deciding contents to be displayed based on the capacitance conditions set by the capacitance conditions setting section.

(9) In the circuit analyzing device of the second list recited in (4), the capacitance value/attribute outputting unit includes a capacitance conditions setting section for setting conditions for the capacitance to be displayed and a display contents deciding section for deciding contents to be displayed based on the setting conditions set by the capacitance conditions setting section and the functional-element attribute library.

(10) In the circuit analyzing device of the third list recited in (5), the per-attribute capacitance value outputting unit includes a capacitance conditions setting section for setting conditions for the capacitance to be displayed and a display contents deciding section for deciding contents to be displayed based on the setting conditions set by the capacitance conditions setting section and the functional-element attribute library.

According to the constitutions recited in (8) through (10), what is to be displayed can be conditionally narrowed down in the analysis, for example, only a given attribute is displayed or only an attribute exceeding a predetermined capacitance value is displayed. Thereby, the generated problem can be more easily learnt, which enables the trouble part to be more efficiently detected.

(11) In the circuit analyzing device of the first list recited in (8), the capacitance conditions setting section sets at least a threshold value with respect to the capacitance value of the functional element, and the display contents deciding section sets a visually identifiable display pattern with respect to the functional element or the functional-element connecting wiring in accordance with the capacitance value of the functional element based on the threshold value.

(12) In the circuit analyzing device of the second list recited in (9), the capacitance conditions setting section sets at least a threshold value with respect to the capacitance value of the functional element, and the display contents deciding section sets a visually identifiable display pattern with respect to the functional element or the functional-element connecting wiring in accordance with the capacitance value of the functional element based on the threshold value and the functional-element attribute library.

(13) In the circuit analyzing device of the third list recited in (10), the capacitance conditions setting section sets at least a threshold value with respect to the per-attribute capacitance value, and the display contents deciding section sets a visually identifiable display pattern with respect to the functional element or the functional-element connecting wiring included in the attribute in accordance with the per-attribute capacitance value based on the functional-element attribute library and the threshold value.

According to the constitutions recited in (11) through (13), the capacitance value can be highlighted in display or hierarchically displayed by setting at least a threshold value. Accordingly, a tendency and characteristics on the whole can be more easily learnt, and the trouble part can be more efficiently found.

(14) In the circuit analyzing devices of the first through third lists recited in (1) through (3), the circuit analyzing device comprises the capacitance value extracting unit for extracting the capacitance value of the functional element from the design information including the layout information of the semiconductor integrated circuit, wherein the capacitance value of the functional element is a total of an input capacitance of a functional element in a subsequent stage linked to an output terminal of the functional element.

According to the foregoing constitution, any problem resulting from the input capacitance of the functional element or a fan-out number can be extracted. Thereby, the factor of the increased capacitance value can be easily analyzed. The constitution can be advantageously applied to a designing stage in which connection information is provided but an actual wiring process has not been completed, and the trouble part can be thereby early found.

(15) In the circuit analyzing devices of the first through third lists recited in (1) through (3), the circuit analyzing device comprises the capacitance value extracting unit for extracting the capacitance value of the functional element from the design information including the layout information of the semiconductor integrated circuit, wherein the capacitance value of the functional element is a total of a wiring capacitance of a wiring linked to an output terminal of the functional element.

According to the foregoing constitution, any problem resulting from a wiring path can be extracted, and the factor of the increased capacitance value can be thereby easily analyzed.

(16) In the circuit analyzing devices of the first through third lists recited in (1) through (3), the circuit analyzing device comprises the capacitance value extracting unit for extracting the capacitance value of the functional element from the design information including the layout information of the semiconductor integrated circuit, wherein the capacitance value of the functional element is a total of an internal capacitance value of the functional element.

According to the foregoing constitution, the functional element having a large capacitance value can be extracted.

(17) In the circuit analyzing devices of the first through third lists recited in (1) through (3), the circuit analyzing device comprises the capacitance value extracting unit for extracting the capacitance value of the functional element from the design information including the layout information of the semiconductor integrated circuit, wherein the capacitance value of the functional element is a total of an input capacitance of a functional element in a subsequent stage linked to an output terminal of the functional element and a wiring capacitance of a wiring linked to the output terminal of the functional element.

According to the foregoing constitution, the functional element having a large output load, that is the functional element whose power consumption or delay is possibly large, can be found.

(18) In the circuit analyzing devices of the first through third lists recited in (1) through (3), the circuit analyzing device comprises the capacitance value extracting unit for extracting the capacitance value of the functional element from the design information including the layout information of the semiconductor integrated circuit, wherein the capacitance value of the functional element is a total of an internal capacitance value of the functional element, an input capacitance of a functional element in a subsequent stage linked to an output terminal of the functional element and a wiring capacitance of a wiring linked to the output terminal of the functional element.

According to the foregoing constitution, the functional element whose power consumption or delay is possibly large, can be found.

(19) In the circuit analyzing devices of the second and third lists recited in (2) and (3), the attribute of the functional element includes information representing a group which the functional element belongs to.

According to the foregoing constitution, the functional elements can be divided into groups, and the capacitance value can be easily analyzed for each group facilitating the analysis of the trouble part.

(20) In the circuit analyzing devices of the second and third lists recited in (2) and (3), the attribute of the functional element includes information representing a group which the functional element belongs to and information representing a group which a functional element linked to an output of the functional element belongs to.

According to the foregoing constitution, the attribute of the functional element and the attribute of the functional element in the subsequent stage are checked so that a problem occurring within one attribute and a problem occurring across two or more attributes can be separately grasped, which facilitates the detection of the problem. Thereby, the trouble part can be more efficiently found.

(21) In the circuit analyzing device recited in (19) or (20), the group denotes information on a layout group representing a bundle of functional elements disposed in vicinity.

According to the foregoing constitution, the layout group which the functional element or the functional element in the subsequent stage belongs to can be learnt from the attribute information. Thereby, a floor plan of the trouble part having a large capacitance can be reviewed and if the layout group should be divided or combined and the like can be decided with more efficiency.

(22) In the circuit analyzing device recited in (19) or (20), the group denotes information on a logical hierarchy representing a bundle of functional elements.

According to the foregoing constitution, if the trouble part having a large capacitance is within the logical hierarchy or between the logical hierarchies can be easily judged, and any part to be logically changed can be easily extracted from the judgment result.

(23) In the circuit analyzing devices of the second and third lists recited in (2) and (3), the attribute of the functional element includes information on a functional-element string continuously linked to the functional element.

According to the foregoing constitution, a capacitance value relating to a specific functional-element string can be extracted from the attribute information, and the trouble part can be analyzed by each path.

(24) In the circuit analyzing devices of the first through third lists recited in (14) through (16), the design information is information on a wiring layout of the circuit in which a rough wiring has been completed.

(25) In the circuit analyzing devices of the first through third lists recited in (14) through (16), the design information is information on a wiring layout of the circuit in which a detailed wiring has been completed.

The followings relate to “a capacitance value of an output terminal of a functional element”.

(26) The circuit analyzing device comprises a capacitance value outputting unit for displaying a functional element in the semiconductor integrated circuit or a functional-element connecting wiring linked to the functional element on a design drawing including layout information of the semiconductor integrated circuit in a discriminating manner in accordance with a capacitance value of an output terminal of the functional element.

(27) The circuit analyzing device comprises a capacitance value/attribute outputting unit for outputting a capacitance value and an attribute of an output terminal of each functional element based on a functional-element at tribute library in which attribute information of the output terminal of each functional element in the semiconductor integrated circuit is stored and the capacitance value of the output terminal of the functional element.

(28) The circuit analyzing device comprises a per-attribute capacitance value operation unit for executing an operation of a capacitance value per attribute based on a functional-element attribute library in which attribute information of an output terminal of a functional element in the semiconductor integrated circuit is stored and the capacitance value of the output terminal of the functional element and a per-attribute capacitance value outputting unit for outputting the per-attribute capacitance value calculated by the per-attribute capacitance value operation unit.

Below is described a circuit analyzing method.

(29) The circuit analyzing method comprises a capacitance value outputting step in which a functional element or a functional-element connecting wiring is displayed on a design drawing including layout information of the semiconductor integrated circuit in a discriminating manner based on a capacitance value of the functional element in the semiconductor integrated circuit.

(30) The circuit analyzing method comprises a capacitance value/attribute outputting step in which a capacitance value and an attribute of each functional element are outputted based on a functional-element attribute library in which attribute information of the functional element in the semiconductor integrated circuit is stored and the capacitance value of the functional element.

(31) The circuit analyzing method comprises a per-attribute capacitance value operation step in which an operation of a capacitance value is executed per attribute based on a functional-element attribute library in which attribute information of a functional element inside the semiconductor integrated circuit is stored and the capacitance value of the functional element and a per-attribute capacitance value outputting step in which a result of the operation per attribute executed in the per-attribute capacitance value operation step is outputted.

Hereinafter, preferred embodiments of a circuit analyzing device and a circuit analyzing method according to the present invention are described in detail referring to the drawings.

### Embodiment 1

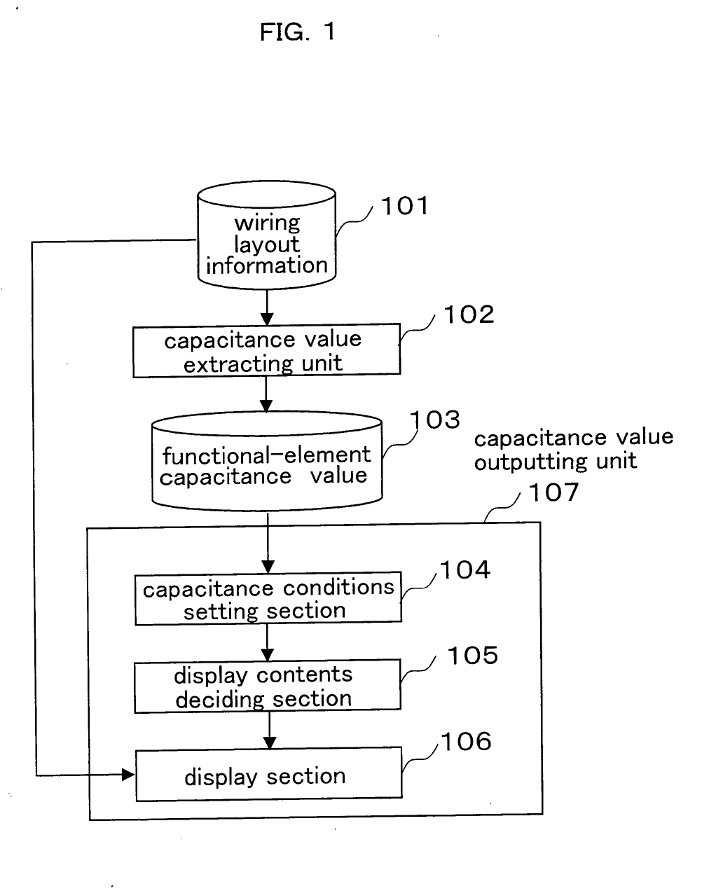

An embodiment 1 of the present invention is described referring to the drawings. Referring to reference numerals in FIG. 1, which shows a constitution of a circuit analyzing device according to the embodiment 1, 101 denotes wiring layout information of a semiconductor integrated circuit, 102 denotes a capacitance value extracting unit for extracting a capacitance value of a functional element (functional-element capacitance value) from the wiring layout information 101, 103 denotes the capacitance value of the functional element extracted by the capacitance value extracting unit 102, and 107 denotes a capacitance value outputting unit for outputting the functional-element capacitance value 103. The capacitance value outputting unit 107 comprises a capacitance conditions setting section 104, a display contents deciding section 105 and a display section 106. For reference, the capacitance value extracting unit 102 may not be included in some cases.

Actions of the respective components are described in detail referring to the drawings.

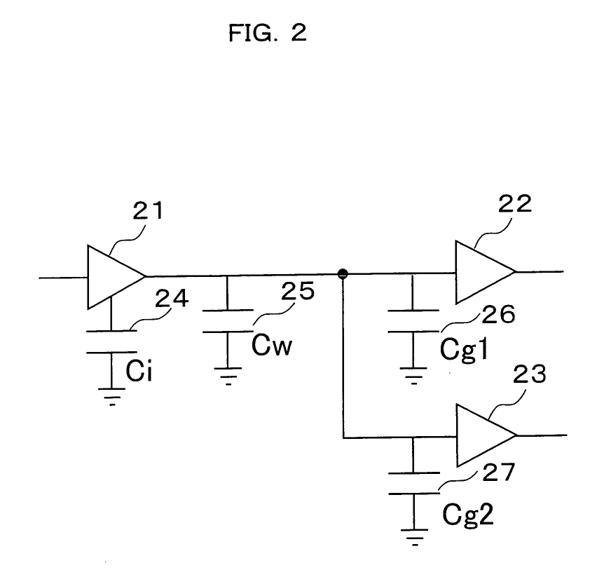

The capacitance value extracting unit 102 extracts the functional-element capacitance value from the wiring layout information 101 of the semiconductor integrated circuit. The functional-element capacitance value extracted by the capacitance value extracting unit 102 is described referring to FIG. 2 showing a capacitance model.

Referring to reference numerals in FIGS. 2, 21, 22 and 23 each denotes a functional elements 24 denotes an internal capacitance Ci of the functional element 21, 25 denotes a wiring capacitance Cw of a wiring linked to an output terminal of the functional element 21, 26 denotes an input capacitance Cg1 of the functional element 22, and 27 denotes an input capacitance Cg2 of the functional element 23. In the capacitance value extracting unit 102, a functional-element capacitance value C0 of the functional element 21 is decided depending on a purpose of the analysis. The functional-element capacitance value C0 is represented by a combination of at least one of the foregoing capacitance values. For example, in the case of the analysis by a total capacitance, the functional-element capacitance value C0 is decided as the total of the capacitance values, that is,
C0=Ci+Cw+Cg1+Cg2

When the internal capacitance Ci of the functional element is smaller than the wiring capacitance Cw and the input capacitances Cg1 and Cg2, the internal capacitance Ci may be omitted to obtain the following.
C0=Cw+Cg1+Cg2

In the case of the analysis without depending on the wiring capacitance Cw, in other words, in the case of the analysis or the like of a part depending on logic and having a large fan-out, it is decided that the only input capacitances Cg1 and Cg2 are used as the following.
C0=Cg1+Cg2

In the case of the analysis of a part depending on a layout factor, in other words, in the case of the analysis or the like of a part whose layout is inappropriate, it is decided that only the wiring capacitance Cw is used as the following.
C0=Cw

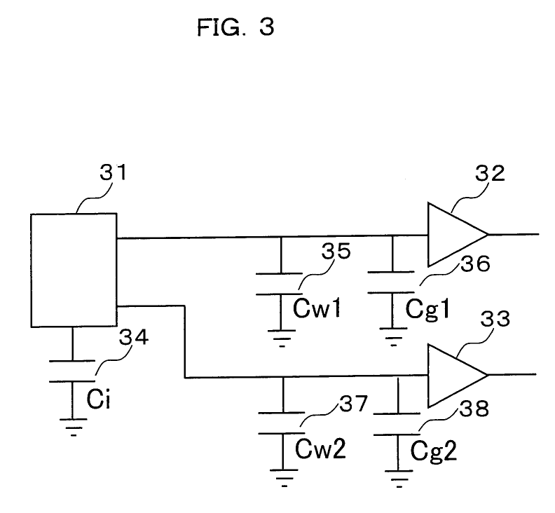

A case in which at least two output terminals are included in the functional element is described referring to FIG. 3. Referring to reference numerals in FIG. 3, 31 denotes a functional element having two output terminals, 32 and 33 each denotes a functional element linked to the respective output terminals of the functional element 31, 34 denotes an internal capacitance Ci of the functional element 31, 35 denotes a wiring capacitance Cw1 of a wiring connecting the functional elements 31 and 32, 36 denotes an input capacitance Cg1 of the functional element 32, 37 denotes a wiring capacitance Cw2 of a wiring connecting the functional elements 31 and 33, and 38 denotes an input capacitance Cg2 of the functional element 33. In the case in which the functional element thus includes at least two output terminals, the before-mentioned calculation is carried out for each output terminal. Then, capacitance values of the respective output terminals are calculated, and a total of the calculated values is used as a functional-element capacitance value C1 of the functional element 31. More specifically, the following is provided in the case of implementing the analysis using the total capacitance,
C1=Ci+Cw1+Cg1+Cw2+Cg2

Alternatively, the internal capacitance C1 is omitted to obtain the following.
C1=Cw1+Cg1+Cw2+Cg2

In the case of the analysis or the like of a part dependent on logic and having a large fan-out, the capacitance values Cw1 and Cw2 are omitted to obtain the following.
C1=Cg1+Cg2

In the case of analyzing a part depending on a layout factor, in other words, in the case of the analysis or the like of a part whose layout is inappropriate, the following is provided.
C1=Cw1+Cw2

Next, conditions for the functional-element capacitance value to be displayed are set by the capacitance conditions setting section 104. A minimum value of the functional-element capacitance value to be displayed is set as the conditions for the functional-element capacitance value to be displayed. Alternatively, in the case of displaying the functional-element capacitance value in a stepwise manner, a display level is set by setting a plurality of capacitance levels and further setting a threshold value with respect to each of the levels. In the display contents deciding section 105, a display pattern is decided with respect to the functional element based on the display conditions set by the capacitance conditions setting section 104. As the display pattern, only those satisfying the display conditions are displayed, or all of the functional-element capacitance values are displayed, among which those satisfying the display conditions are highlighted. When the plurality of capacitance levels is set by the capacitance conditions setting section 104, the display pattern is set with respect to each of the capacitance levels, and the display pattern is decided with respect to the functional element and the functional-element connecting wiring in accordance with the functional-element capacitance value.

Next, the functional element and the functional-element connecting wiring are displayed according to the wiring layout information 101 and the display pattern decided by the display contents deciding section 105 in the display section 106.

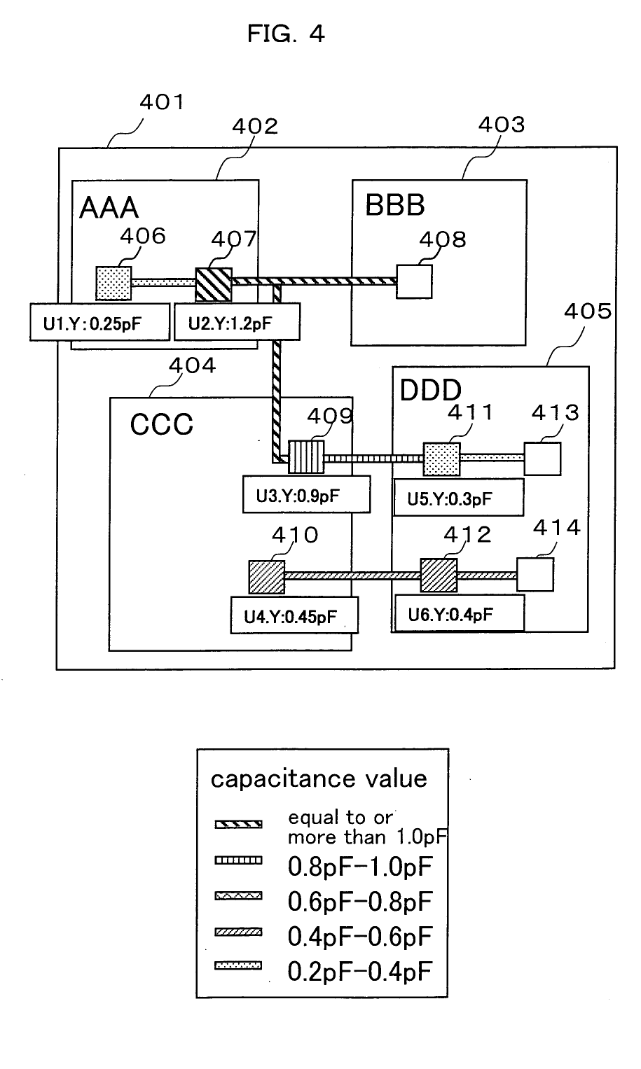

Referring to reference numerals in FIG. 4 showing a display example of the functional-element capacitance value, 401 denotes an entire semiconductor integrated circuit, 402-405 each denotes a layout group representing a group of functional elements disposed in vicinity, 406-414 each denotes a part of the functional elements included in the respective layout groups. Values shown after the colon (:) in rectangular brackets below the respective functional elements denote the respective functional-element capacitance values. A result of setting the capacitance levels of five stages, from 0.2 pF to 1.0 pF, and the threshold values thereof with respect to the circuit is a display example shown in FIG. 4. Hatched parts and reticulated parts denote the display pattern. It is learnt from the display result of the present embodiment that the capacitance of the functional element 407 is large because the functional element 407 is linked to the two layout groups 403 and 404 which are disposed distant from each other.

As described, according to the present embodiment, the functional element or the wiring having a large functional-element capacitance value and undergoing any problem in terms of power and speed can be visually confirmed, which enables the early detection of the problem. Further, the functional-element information and the functional-element capacitance value of a part to be noted are both displayed so that accurate information of the trouble part can be obtained.

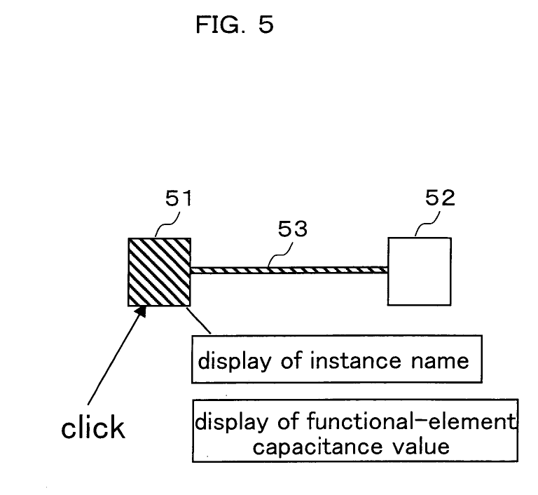

Referring to reference numerals in FIG. 5 showing another display example of the functional element, 51 and 52 each denotes a functional element, and 53 denotes a wiring connecting the functional elements 51 and 52. When a functional element is clicked, an instance name and attribute information of the functional element are displayed.

In order to respond to a part judged to be undergoing trouble because of a large functional-element capacitance value after the functional-element capacitance value is displayed in the described manner, the judgment result is fed back to a floor plan or architecture so that countermeasures can be examined. In doing so, the countermeasures can be efficiently examined when the result obtained according to the present embodiment is used.

In the present embodiment, the plurality of patterns is used to discriminate the functional element and the wiring. As an alternative method, a plurality of colors may be used for the purpose.

Different settings may be employed depending on usage in place of setting the plurality of threshold values with respect to the functional-element capacitance value in the capacitance conditions setting section 104. For example, a functional element of a maximum capacitance may be designated, or a few top functional-element capacitance values may be designated in order to narrow the search of the part to be noted. Accordingly, a more eye-friendly display can be achieved.

In the present embodiment, macro blocks such as a memory and a functional block may be used as a functional element so that the macroblocks can be handled in the same manner. Further, a functional block, which is not finely designed, may be also handled as a functional element so that the functional-element capacitance value between the functional elements can be checked in an initial stage of the designing process. As a result, a trouble part in the initial floor plan or block division can be early detected, which enables the early feedback. Further, in the case of the macro blocks having a large number of output terminals, it is preferable in some cases that the analysis be individually carried out per output terminal. In such a case, the output terminal is handled in the same manner as the functional element so that the analysis can be effectively carried out.

Further, the circuit in which a detailed wiring has been completed is used in the example described in the present embodiment. However, the present invention can be applied to a circuit in an early designing stage in which a rough wiring is only provided if the functional-element capacitance value is obtained by means of the Steiner model. In such a manner, the early detection of the trouble part and the early feedback can be achieved, and a designing period can be thereby shortened.

In the present embodiment, the capacitance value extracting unit for extracting the capacitance value of each functional element is provided, however, a comparable effect can be obtained in the case of using the functional-element capacitance value which is already extracted.

### Embodiment 2

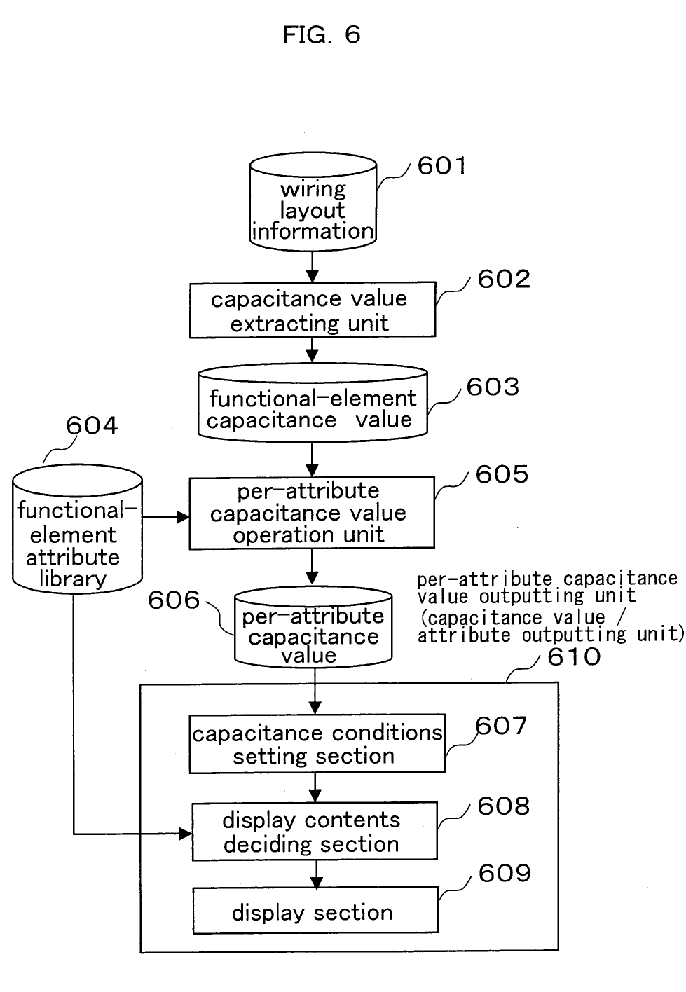

An embodiment 2 of the present invention is described referring to the drawings. FIG. 6 is a block diagram illustrating a circuit analyzing device according to the embodiment 2. The embodiment 2 is different to the embodiment 2 in that a functional-element attribute library 604 and a per-attribute capacitance value operation unit 605 are further provided. The rest of the constitution conforms to the constitution recited in the embodiment 1. Below are described differences between the embodiments 1 and 2.

A reference numeral 610 denotes a per-attribute capacitance value outputting unit for outputting a per-attribute capacitance value 606. The per-attribute capacitance value outputting unit 610 comprises a capacitance conditions setting section 607, a display contents deciding section 608 and a display section 609. The capacitance value extracting unit 602 may be omitted in some cases. A printing section may be provided in place of the display section.

The functional-element attribute library 604 corresponds to wiring layout information 601 and creates the information 601 using connection information or wiring layout information of a semiconductor integrated circuit. In the functional-element attribute library 604, an instance name and attribute information of a functional element is recited with respect to all of the functional elements included in the semiconductor integrated circuit.

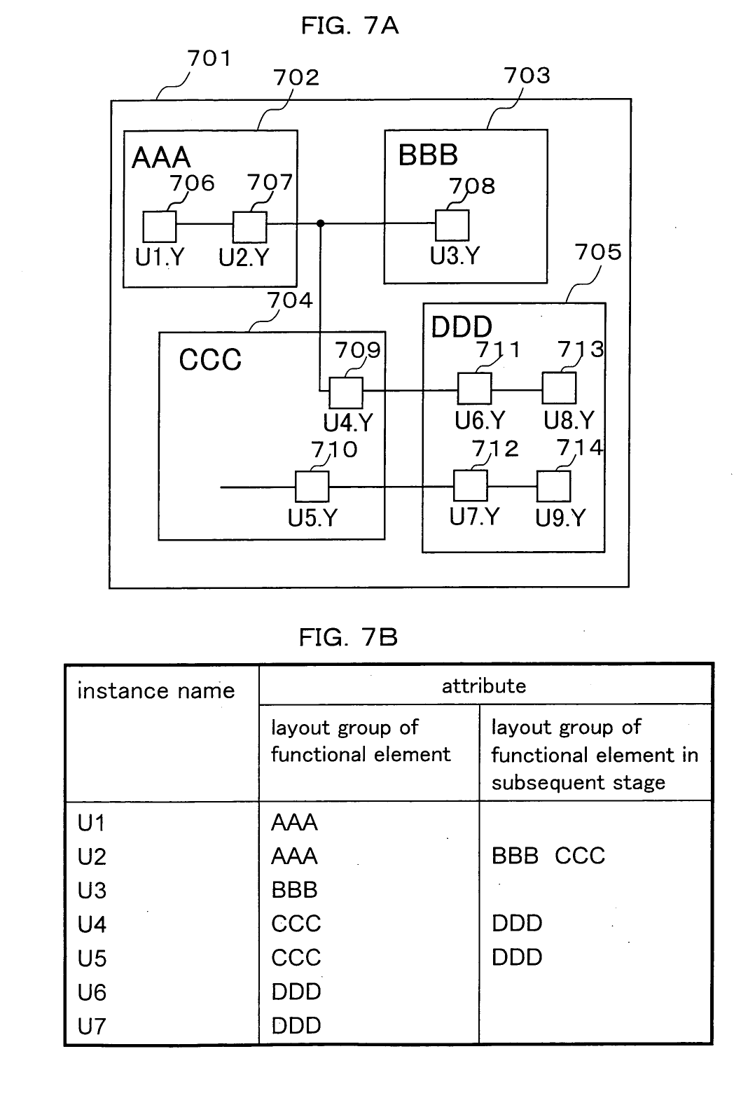

Referring to FIG. 7, actions of the functional-element attribute library 604 and the per-attribute capacitance value operation unit 605 are described. FIG. 7 are examples of setting an attribute of the functional element with respect to the circuit used in the embodiment 1, wherein FIG. 7A is a block diagram illustrating a layout of the semiconductor integrated circuit, and FIG. 7B is a description example of the functional-element attribute library 604 in the case of the circuit configuration shown in FIG. 7A.

Referring to reference numerals in FIG. 7A, 701 denotes the semiconductor integrated circuit, 702-705 each denotes a layout group representing a group of functional elements disposed in vicinity, 706-714 each denotes a part of the functional elements included in the respective layout groups. In the present embodiment, information of the layout group which the functional element belongs to and information of the layout group which the functional element in a subsequent stage belongs to both serve as the attribute of the functional element. More specifically, as shown in FIG. 7B, the information of the respective functional elements and the information of the layout groups which the respective functional elements belong to are recited in the functional-element attribute library 604. Further, in the case in which a wiring linked to an output terminal of the functional element is linked to any of the other layout groups, information on all of the layout groups linked to the output terminal are also recited. For example, the functional element 707 belongs to a layout group AAA, and a wiring linked to an output terminal thereof is linked to a layout group BBB and a layout group CCC. Therefore, the attribute recited in the functional-element attribute library 604 denotes the layout group AAA of the functional element 707 and the layout groups BBB and CCC of the functional element in the subsequent stage.

Next, the per-attribute capacitance value operation unit 605 refers to the attribute information of each functional element recited in the functional-element attribute library 604, adds the functional-element capacitance values having exactly the same attribute, and thereby calculates the per-attribute capacitance value 606. For example, in the case of FIG. 7, the functional element 711 and the functional element 712 have the same attribute (DDD), therefore, the capacitance values thereof are added. The capacitance values of the functional element 709 and the functional element 710 are added in the same manner. The process is carried out to all of the functional elements in the semiconductor integrated circuit. As a result, a sum of the capacitances of the functional elements respectively limited to AAA, BBB and DDD, a sum of the capacitances connecting AAA, BBB and CCC and a sum of the capacitances connecting CCC and DDD are obtained in the present embodiment. Accordingly, if a part of a large capacitance is within the layout group or between the layout groups can be judged.

As described, the layout group which the functional element belongs to and the layout group as the output destination are used as the attribute information so that the total of the capacitance values of the respective layout groups and the total of the capacitance values of the wirings between the layout groups are calculated. Thereby, the problem by each block and the problem resulting from the connection of the blocks can be separately identified, which facilitates the analysis of the factor. Further, the total value of the capacitance values between the respective layout groups is explicitly shown so that the change of the floor plan can be efficiently reviewed.

According to the present embodiment, the capacitances of the functional elements having the same attribute are summed so as to obtain the capacitance value per attribute. Alternatively, the total of the capacitance values calculated in the foregoing process may be divided by the number of the wirings included in the respective attributes so as to calculate the capacitance value of each wiring. Thereby, a part whose capacitance does not have a considerably large dimension but is relatively large can be extracted.

According to the present embodiment, the method of graphically displaying the capacitance value on the layout drawing of the semiconductor integrated circuit is described. However, the capacitance value and the attribute may be alternatively displayed in the form of text so that accurate information on the functional element or attribute having a maximum capacitance value and the functional element or attribute in the higher rank of the dimension of the value can be obtained and a filtering process or the like can be easily implemented to the output result.

### Embodiment 3

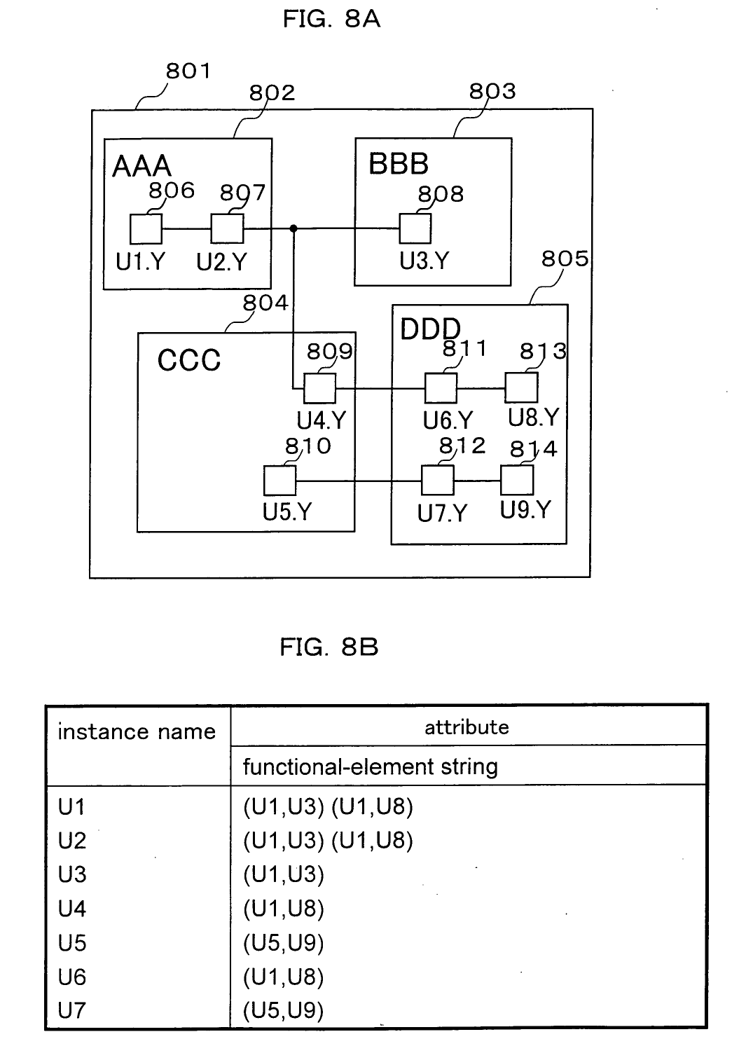

An embodiment 3 of the present invention is described referring to FIG. 8. A constitution according to the present embodiment conforms to that of the embodiment 2. However, processes of the functional-element attribute library 604 and the per-attribute capacitance value operation unit 605 are different in the present embodiment.

In FIG. 8A, functional-element strings are defined with respect to a circuit 801, and the functional elements have the respective functional-element strings in which they are included as an attribute thereof. More specifically, the functional-element string is represented by a combination of a name of a functional element as a starting point and a name of a functional element as an ending point and is used as the attribute. In FIG. 8A, a functional element 806 and a functional element 810, which are not provided with a connecting line on left side, are used as the starting point, while a functional element 808 and a functional element 814, which are not provided with a connecting line on right side, are used as the ending point, and a list connecting them is designated as the functional-element string. Based on the foregoing definition, the attributes of the respective functional elements are set as shown in FIG. 8B. These lists are often limitedly defined as from a flip-flop to a flip-flop, which corresponds to one cycle of a clock. To be brief, the starting point and the ending point denote the flip-flops.

A total of capacitances of the functional elements included in the respective functional-element strings is obtained in the per-attribute capacitance value operation unit 605 using the attribute. The capacitance of each of the functional-element strings is obtained and thereby compared and analyzed so that a trouble part can be extracted as an action of the relevant functional-element string. Thereby, the circuit can be efficiently modified.

In the present embodiment, the starting point and the ending point are combined to serve as the attribute, however, the same effect can be achieved by designating one of the starting and ending points as the attribute.

Further, as the attribute information of each functional element, information of a logical hierarchy representing a bundle of functional elements, other than the information on the layout group and the information of the starting and ending points of the functional-element string described above, can be used, or at least two information of the above informations can be combined and used. Using the information of the logical hierarchy as the attribute information, correction of the logic re-division of the functions can be reviewed.

The present invention is not limited to the foregoing embodiments, and can be variously modified and implemented within the scope of its technical idea.

As thus far described in detail, as a first advantage of the present invention, the functional element or the functional-element connecting wiring are displayed on the layout drawing of the semiconductor integrated circuit in the discriminating manner in accordance with the capacitance value of each functional element or the per-attribute capacitance value so that the capacitance value can be visually confirmed and the part having a large capacitance can be efficiently detected as the trouble part.

Further, as a second advantage of the present invention, the capacitance value of each functional element and the attribute information of the functional element supplied by the functional-element attribute library are both outputted so that the capacitance values can be classified based on the attribute, which enables the capacitance values to be easily narrowed down in the analysis and the trouble part to be easily identified.

Further, as a third advantage of the present invention, the operation of the capacitance value is executed per attribute so that the capacitance values can be collectively obtained per attribute. Thereby, any trouble part unidentifiable based on each individual functional element can be easily detected.

Further, as a fourth advantage of the present invention, the capacitance values of the functional elements having the same attribute are summed so as to calculate the capacitance value per attribute. Thereby, the attribute having a large sum of the capacitance values can be found, and the part whose capacitance is not individually large but is relatively large on the whole can be extracted.

Further, as a fifth advantage of the present invention, the total value of the capacitance values calculated by summing the functional-element capacitance values having the same attribute is divided by the number of the wirings included in the respective attributes so as to calculate the capacitance value in each wiring. Thereby, the part whose capacitance does not have a significant dimension but is relatively large can be extracted.

Further, as a sixth advantage of the present invention, the display contents are decided based on the conditions of the selected capacitance and the functional-element attribute library so that a specific attribute can be displayed and those having a capacitance value exceeding the predetermined capacitance value can be displayed. It thereby becomes easier to grasp any trouble, and the trouble part can be more efficiently found.

Further, as a seventh advantage of the present invention, the input capacitance of the functional element linked to the output of the functional element is used as the functional-element capacitance value so that the problem resulting from the input capacitance of the functional element and the problem resulting from the fan-out number can be separately extracted, and the factor analysis can be easily performed. Further, the present invention can be advantageously applied to the early stage of the designing process in which the detailed wiring information is not provided, and the trouble detection can be early performed.

Further, as an eighth advantage of the present invention, the wiring capacitance of the wiring linked to the output of the functional element is used as the functional-element capacitance value so that the problem resulting from the wiring path can be extracted separately from the problem resulting from the input capacitance. Thereby, it becomes easier to analyze the factor of an increased capacitance value.

Further, as a ninth advantage of the present invention, the sum of the input capacitance of the functional element and the wiring capacitance of the wiring which are linked to the output of the functional element is used as the functional-element capacitance value so that the functional element whose output load is large, that is the functional element whose power consumption or delay value is possibly large, can be found.

Further, as a tenth advantage of the present invention, the respective functional elements additionally have the information of the functional element in the subsequent stage thereof as the attribute so that the problem occurring in an attribute and the problem occurring across at least two attributes can be separated. Thereby, the problem can be more easily grasped, and the trouble part can be more efficiently identified.

Further, as an 11th advantage of the present invention, the layout group is provided as the attribute information of the functional element so that the review of the floor plan and review of the division, combination or the like of the layout group can be efficiently carried out based on the information of the layout group relating to the trouble part having a large capacitance.

Further, as a 12th advantage of the present invention, the logical hierarchy is provided as the attribute information of the functional element so that the logic correction and the division, combination or the like of the function can be reviewed based on the information on the logical hierarchy relating to the trouble part having a large capacitance.

Further, as a 13th advantage of the present invention, as the attribute information of the functional element is provided the information on the continuous functional-element string including the relevant functional element. Thereby, the analysis can be carried out for each path.

The circuit analyzing device according to the present invention is capable of easily extracting the part undergoing the trouble in terms of power and speed based on the analysis result of the capacitance value, and therefore, is applicable to a mobile device demanding a high performance and a low-power operation, an analyzing device of a stationary type for a semiconductor integrated circuit demanding the low-power operation in order to satisfy an ongoing environmental trend for reducing noises and the like.

1. A circuit analyzing device comprising:
a capacitance value extracting unit for extracting a capacitance value of a functional element from design information including layout information of a semiconductor integrated circuit; and
a capacitance value outputting unit for displaying the functional element in the semiconductor integrated circuit or a functional-element connecting wiring linked to the functional element on a design drawing including the layout information of the semiconductor integrated circuit in a discriminating manner in accordance with the capacitance value of the functional element.

2. A circuit analyzing device comprising:
a capacitance value extracting unit for extracting a capacitance value of a functional element from design information including layout information of a semiconductor integrated circuit; and
a capacitance value/attribute outputting unit for outputting the capacitance value and an attribute of each functional element based on a functional-element attribute library in which attribute information of the functional element in the semiconductor integrated circuit is stored and the capacitance value of the functional element.

3. A circuit analyzing device comprising:
a capacitance value extracting unit for extracting a capacitance value of a functional element from design information including layout information of a semiconductor integrated circuit;
a per-attribute capacitance value operation unit for executing an operation of the capacitance value per attribute based on a functional-element attribute library in which attribute information of the functional element in the semiconductor integrated circuit is stored and the capacitance value of the functional element; and
a per-attribute capacitance value outputting unit for outputting the capacitance value per attribute calculated by the per-attribute capacitance value operation unit.

4. A circuit analyzing device as claimed in claim 2, wherein
the capacitance value/attribute outputting unit displays the functional element or the functional-element connecting wiring on the designing drawing including the layout of the semiconductor integrated circuit in the discriminating manner in accordance with the capacitance value of the functional element.

5. A circuit analyzing device as claimed in claim 3, wherein
the per-attribute capacitance value outputting unit displays the functional element or the functional-element connecting wiring on the designing drawing including the layout of the semiconductor integrated circuit in the discriminating manner in accordance with the per-attribute capacitance value.

6. A circuit analyzing device as claimed in claim 3, wherein
the per-attribute capacitance value operation unit sums the functional-element capacitance values having the same attribute so as to calculate the capacitance value per attribute.

7. A circuit analyzing device as claimed in claim 3, wherein
the per-attribute capacitance value operation unit divides a total of the capacitance values calculated by summing the functional-element capacitance values having the same attribute by number of the wirings included in the each attribute and thereby calculates the capacitance value of each wiring per attribute.

8. A circuit analyzing device as claimed in claim 1, wherein
the capacitance value outputting unit includes a capacitance conditions setting section for setting conditions for the capacitance to be displayed and a display contents deciding section for deciding contents to be displayed based on the capacitance conditions set by the capacitance conditions setting section.

9. A circuit analyzing device as claimed in claim 4, wherein
the capacitance value/attribute outputting unit includes a capacitance conditions setting section for setting conditions for the capacitance to be displayed and a display contents deciding section for deciding contents to be displayed based on the setting conditions set by the capacitance conditions setting section and the functional-element attribute library.

10. A circuit analyzing device as claimed in claim 5, wherein
the per-attribute capacitance value outputting unit includes a capacitance conditions setting section for setting conditions for the capacitance to be displayed and a display contents deciding section for deciding contents to be displayed based on the setting conditions set by the capacitance conditions setting section and the functional-element attribute library.

11. A circuit analyzing device as claimed in claim 8, wherein
the capacitance conditions setting section sets at least a threshold value with respect to the capacitance value of the functional element, and the display contents deciding section sets a visually identifiable display pattern with respect to the functional element or the functional-element connecting wiring in accordance with the capacitance value of the functional element based on the threshold value.

12. A circuit analyzing device as claimed in claim 9, wherein
the capacitance conditions setting section sets at least a threshold value with respect to the capacitance value of the functional element, and the display contents deciding section sets a visually identifiable display pattern with respect to the functional element or the functional-element connecting wiring in accordance with the capacitance value of the functional element based on the threshold value and the functional-element attribute library.

13. A circuit analyzing device as claimed in claim 10, wherein
the capacitance conditions setting section sets at least a threshold value with respect to the per-attribute capacitance value, and the display contents deciding section sets a visually identifiable display pattern with respect to the functional element or the functional-element connecting wiring included in the attribute in accordance with the per-attribute capacitance value based on the functional-element attribute library and the threshold value.

14. A circuit analyzing device as claimed in claim 1, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element.

15. A circuit analyzing device as claimed in claim 2, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element.

16. A circuit analyzing device as claimed in claim 3, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element.

17. A circuit analyzing device as claimed in claim 1, comprising the capacitance value extracting unit for extracting the capacitance value of the functional element from the design information including the layout information of the semiconductor integrated circuit, wherein
the capacitance value of the functional element is a total of a wiring capacitance of a wiring linked to an output terminal of the functional element.

18. A circuit analyzing device as claimed in claim 2, comprising the capacitance value extracting unit for extracting the capacitance value of the functional element from the design information including the layout information of the semiconductor integrated circuit, wherein
the capacitance value of the functional element is a total of a wiring capacitance of a wiring linked to an output terminal of the functional element.

19. A circuit analyzing device as claimed in claim 3, comprising the capacitance value extracting unit for extracting the capacitance value of the functional element from the design information including the layout information of the semiconductor integrated circuit, wherein
the capacitance value of the functional element is a total of a wiring capacitance of a wiring linked to an output terminal of the functional element.

20. A circuit analyzing device as claimed in claim 1, comprising the capacitance value extracting unit for extracting the capacitance value of the functional element from the design information including the layout information of the semiconductor integrated circuit, wherein
the capacitance value of the functional element is a total of an internal capacitance value of the functional element.

21. A circuit analyzing device as claimed in claim 2, comprising the capacitance value extracting unit for extracting the capacitance value of the functional element from the design information including the layout information of the semiconductor integrated circuit, wherein
the capacitance value of the functional element is a total of an internal capacitance value of the functional element.

22. A circuit analyzing device as claimed in claim 3, comprising the capacitance value extracting unit for extracting the capacitance value of the functional element from the design information including the layout information of the semiconductor integrated circuit, wherein
the capacitance value of the functional element is a total of an internal capacitance value of the functional element.

23. A circuit analyzing device as claimed in claim 1, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element and a wiring capacitance of a wiring linked to the output terminal of the functional element.

24. A circuit analyzing device as claimed in claim 2, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element and a wiring capacitance of a wiring linked to the output terminal of the functional element.

25. A circuit analyzing device as claimed in claim 3, comprising the capacitance value extracting unit for extracting the capacitance value of the functional element from the design information including the layout information of the semiconductor integrated circuit, wherein
the capacitance value of the functional element is a total of an input capacitance of a functional element in a subsequent stage linked to an output terminal of the functional element and a wiring capacitance of a wiring linked to the output terminal of the functional element.

26. A circuit analyzing device as claimed in claim 1, comprising the capacitance value extracting unit for extracting the capacitance value of the functional element from the design information including the layout information of the semiconductor integrated circuit, wherein
the capacitance value of the functional element is a total of an internal capacitance value of the functional element, an input capacitance of a functional element in a subsequent stage linked to an output terminal of the functional element and a wiring capacitance of a wiring linked to the output terminal of the functional element.

27. A circuit analyzing device as claimed in claim 2, comprising the capacitance value extracting unit for extracting the capacitance value of the functional element from the design information including the layout information of the semiconductor integrated circuit, wherein
the capacitance value of the functional element is a total of an internal capacitance value of the functional element, an input capacitance of a functional element in a subsequent stage linked to an output terminal of the functional element and a wiring capacitance of a wiring linked to the output terminal of the functional element.

28. A circuit analyzing device as claimed in claim 3, comprising the capacitance value extracting unit for extracting the capacitance value of the functional element from the design information including the layout information of the semiconductor integrated circuit, wherein
the capacitance value of the functional element is a total of an internal capacitance value of the functional element, an input capacitance of a functional element in a subsequent stage linked to an output terminal of the functional element and a wiring capacitance of a wiring linked to the output terminal of the functional element.

29. A circuit analyzing device as claimed in claim 2, wherein
the attribute of the functional element includes information representing a group which the functional element belongs to.

30. A circuit analyzing device as claimed in claim 3, wherein
the attribute of the functional element includes information representing a group which the functional element belongs to.

31. A circuit analyzing device as claimed in claim 2, wherein
the attribute of the functional element includes information representing a group which the functional element belongs to and information representing a group which a functional element linked to an output of the functional element belongs to.

32. A circuit analyzing device as claimed in claim 3, wherein
the attribute of the functional element includes information representing a group which the functional element belongs to and information representing a group which a functional element linked to an output of the functional element belongs to.

33. A circuit analyzing device as claimed in claim 29, wherein
the group denotes information on a layout group representing a bundle of functional elements disposed in vicinity.

34. A circuit analyzing device as claimed in claim 30, wherein
the group denotes information on a layout group representing a bundle of functional elements disposed in vicinity.

35. A circuit analyzing device as claimed in claim 29, wherein
the group denotes information on a logical hierarchy representing a bundle of functional elements.

36. A circuit analyzing device as claimed in claim 30, wherein
the group denotes information on a logical hierarchy representing a bundle of functional elements.

37. A circuit analyzing device as claimed in claim 2, wherein
the attribute of the functional element includes information on a functional-element string continuously linked to the functional element.

38. A circuit analyzing device as claimed in claim 3, wherein
the attribute of the functional element includes information on a functional-element string continuously linked to the functional element.

39. A circuit analyzing device as claimed in claim 14, wherein
the design information is information on a wiring layout of the circuit in which a rough wiring has been completed.

40. A circuit analyzing device as claimed in claim 17, wherein
the design information is information on a wiring layout of the circuit in which a rough wiring has been completed.

41. A circuit analyzing device as claimed in claim 20, wherein
the design information is information on a wiring layout of the circuit in which a rough wiring has been completed.

42. A circuit analyzing device as claimed in claim 14, wherein
the design information is information on a wiring layout of the circuit in which a detailed wiring has been completed.

43. A circuit analyzing device as claimed in claim 17, wherein
the design information is information on a wiring layout of the circuit in which a detailed wiring has been completed.

44. A circuit analyzing device as claimed in claim 20, wherein
the design information is information on a wiring layout of the circuit in which a detailed wiring has been completed.

45. A circuit analyzing device comprising:
a capacitance value extracting unit for extracting a capacitance value of an output terminal of a functional element from design information including layout information of a semiconductor integrated circuit; and
a capacitance value outputting unit for displaying the functional element in the semiconductor integrated circuit or a functional-element connecting wiring linked to the functional element on a design drawing including the layout information of the semiconductor integrated circuit in a discriminating manner in accordance with the capacitance value of the output terminal of the functional element.

46. A circuit analyzing device comprising:
a capacitance value extracting unit for extracting a capacitance value of an output terminal of a functional element from design information including layout information of a semiconductor integrated circuit; and
a capacitance value/attribute outputting unit for outputting the capacitance value and an attribute of the output terminal of each functional element based on a functional-element attribute library in which attribute information of the output terminal of each functional element in the semiconductor integrated circuit is stored and the capacitance value of the output terminal of the functional element.

47. A circuit analyzing device comprising:
a capacitance value extracting unit for extracting a capacitance value of an output terminal of a functional element from design information including layout information of a semiconductor integrated circuit;
a per-attribute capacitance value operation unit for executing an operation of the capacitance value per attribute based on a functional-element attribute library in which attribute information of the output terminal of the functional element in the semiconductor integrated circuit is stored and the capacitance value of the output terminal of the functional element; and
a per-attribute capacitance value outputting unit for outputting the per-attribute capacitance value calculated by the per-attribute capacitance value operation unit.

48. A circuit analyzing method comprising:
a capacitance value extracting step in which a capacitance value of a functional element is extracted from design information including layout information of a semiconductor integrated circuit; and
a capacitance value outputting step in which the functional element or a functional-element connecting wiring is displayed on a design drawing including the layout information of the semiconductor integrated circuit in a discriminating manner based on the capacitance value of the functional element in the semiconductor integrated circuit.

49. A circuit analyzing method comprising:
a capacitance value extracting step in which a capacitance value of a functional element is extracted from design information including layout information of a semiconductor integrated circuit; and
a capacitance value/attribute outputting step in which the capacitance value and an attribute of each functional element are outputted based on a functional-element attribute library in which attribute information of the functional element in the semiconductor integrated circuit is stored and the capacitance value of the functional element.

50. A circuit analyzing method comprising:
a capacitance value extracting step in which a capacitance value of a functional element is extracted from design information including layout information of a semiconductor integrated circuit;
a per-attribute capacitance value operation step in which an operation of the capacitance value is executed per attribute based on a functional-element attribute library in which attribute information of the functional element in the semiconductor integrated circuit is stored and the capacitance value of the functional element; and
a per-attribute capacitance value outputting step in which a result of the operation per attribute executed in the per-attribute capacitance value operation step is outputted.
